(19) United States
(12) Patent Application Publication
(10) Pub. No.: US 2019/0131586 A1
(43) Pub. Date: May 2, 2019

(54) DISPLAY SUBSTRATE, A MANUFACTURING METHOD THEREOF AND A DISPLAY DEVICE

(71) Applicant: Wuhan China Star Optoelectronics Semiconductor Display Technology Co., Ltd., Wuhan, Hubei (CN)

(72) Inventor: Yun YU, Wuhan, Hubei (CN)

(21) Appl. No.: 15/749,206

(22) PCT Filed: Dec. 4, 2017
(86) PCT No.: PCT/CN2017/114454

§ 371 Date: Jan. 31, 2018

(30) Foreign Application Priority Data
Oct. 27, 2017 (CN) 201711056345.9

(51) Int. Cl. H01L 51/56; H01L 51/00; H01L 27/32; H01L 51/52

(52) U.S. Cl. CPC H01L 51/56; H01L 51/5237; H01L 27/32; H01L 51/003

(57) ABSTRACT

The present disclosure discloses a display substrate, comprising an inorganic film layer; a substrate film layer disposed on one side surface and four sides of the inorganic film layer, partially covered by the substrate film layer; a thin film transistor, OLED layer and encapsulation layer disposed on the substrate film layer. A manufacturing method thereof, comprising the following steps: depositing an inorganic film layer on a carrier substrate; coating the substrate film layer on one side surface and four sides of the inorganic film layer to partially cover the inorganic film layer; preparing a thin film transistor on the substrate film layer; preparing an OLED layer on the thin film transistor; preparing an encapsulation layer on the OLED layer. The present disclosure can effectively reduce the uneven area of the thickness of the edge film layer of the display substrate, and increases the utilization rate of the used area.

### RELATED APPLICATIONS

The present application is a National Phase of International Application Number PCT/CN2017/114454, filed Dec. 4, 2017, and claims the priority of China Application No. 201711056345.9, filed Oct. 27, 2017.

### FIELD OF THE DISCLOSURE

The disclosure relates to a display substrate manufacturing field, and more particularly to a display substrate, its manufacturing method and a display device.

### BACKGROUND

Due to its advantages of light weight, large area coating, high temperature resistance and transparency, plastic polymers are widely used as a preparation material for a flexible display substrate.

In the prior art, a manufacturing process of a display substrate is generally shown as: coating a substrate film layer 9 on a carrier substrate 8, as shown in FIG. 2, which is a schematic diagram showing a structure of the display substrate in the prior art. A technical problem of the structure is that due to a surface tension caused by a flow of a liquid, after the substrate film layer 9 is baked and solidified, an uneven film layer area 9a is formed in an edge region of the substrate film layer 9. For example, when a thickness of a coated substrate film layer 9 in FIG. 1 is about 10 μm, an area H of the uneven film layer area 9a is about 3 to 5 mm.

In addition, when the thickness of the coated substrate film layer 9 increases, the area of the uneven film layer area 9a on the structure of the display substrate increases, as shown in FIG. 2, which is the schematic diagram showing a structure of the display substrate in the prior art. When a coating thickness of the substrate film layer 9 reaches 15˜20 μm, an area range T of an uneven film layer area 9a increases to 5˜10 mm.

In summary, a coating method of an existing substrate may cause problems of the uneven film layer of the edge of the substrate and reduce an effective utilization area of the substrate.

### SUMMARY

The technical problem to be solved by a present disclosure is to provide a display substrate, a manufacturing method thereof and a display device, which effectively reduces a range of an uneven area of a thickness of an edge film layer of the display substrate, and increases an utilization rate of a used area of the substrate.

In order to solve an above technical problem, the embodiments of the present disclosure provide the display substrate, comprising: an inorganic film layer; a substrate film layer disposed on one side and four sides of the inorganic film layer, wherein the substrate film layer partially covers the inorganic film layer; a thin film transistor, an OLED layer and an encapsulation layer disposed on the substrate film layer.

Wherein a thermal expansion coefficient of a material used for the inorganic film layer is the same as or similar to the thermal expansion coefficient of the material used for the substrate film layer.

Wherein the material of the inorganic film layer is a silicon or a silicon dioxide, and the material of the substrate film layer is a polyimide.

Wherein the thickness of the inorganic film layer is smaller than the thickness of the substrate film layer, and the thickness of the inorganic film layer is 100˜500 nm.

Wherein a distance between a boundary of the inorganic film layer and the boundary of the substrate film layer ranges 3˜10 mm.

In order to solve the above technical problem, the present disclosure further provides a manufacturing method of the display substrate, comprising a following steps: depositing the inorganic film layer on a carrier substrate; coating the substrate film layer on the inorganic film layer, and coating the substrate film layer on a one side surface and four sides of the inorganic film layer to partially cover the inorganic film layer; preparing the thin film transistor on the substrate film layer; preparing an OLED layer on the thin film transistor; preparing an encapsulation layer on the OLED layer.

Wherein further comprises peeling off the carrier substrate to form the display substrate.

Wherein in the step of depositing the inorganic film layer, the thickness of the inorganic film layer is 100˜500 nm; the thermal expansion coefficient of the material used for the inorganic film layer is the same as or similar to the thermal expansion coefficient of the material used for the substrate film layer.

Wherein in the step of coating the substrate film layer on the inorganic film layer, a distance between a boundary of the inorganic film layer and a boundary of the substrate film layer ranges 3˜10 mm.

In order to solve the above technical problem, the present disclosure further provides the display device, wherein, the display device comprises the display substrate, the display substrate comprising: the inorganic film layer; the substrate film layer disposed on one side surface and four sides of the inorganic film layer, wherein the substrate film layer partially covers the inorganic film layer; the thin film transistor, an OLED layer and an encapsulation layer deposes on the substrate film layer.

Wherein the thermal expansion coefficient of the material used for the inorganic film layer is the same as or similar to the thermal expansion coefficient of the material used for the substrate film layer.

Wherein the material of the inorganic film layer is the silicon or the silicon dioxide, and the material of the substrate film layer is the polyimide.

Wherein the thickness of the inorganic film layer is smaller than the thickness of the substrate film layer; the thickness of the inorganic film layer is 100-500 nm.

Wherein the distance between the boundary of the inorganic film layer and the boundary of the substrate film layer ranges 3˜10 mm.

The implementation of the display substrate, the manufacturing method and the display device provided by the present disclosure has the following advantages: depositing the inorganic film layer on a carrier substrate; coating the substrate film layer on the inorganic film layer, and coating the substrate film layer on a one side surface and four sides of the inorganic film layer to partially cover the inorganic film layer which effectively reduce the range of the uneven area of the thickness of the edge film layer of the display substrate, and increases the utilization rate of the used area of the substrate.

### BRIEF DESCRIPTION OF THE DRAWINGS

To describe the technical solutions in the embodiments of the present disclosure or in the prior art more clearly, the following briefly introduces the accompanying figures required for describing the embodiments or the prior art; apparently, the accompanying figures in the following description show merely some embodiments of the present disclosure, and persons of ordinary skill in the art may still derive other figures from these accompanying figures without creative efforts.

FIG. 1 is a schematic structural diagram of a display substrate prepared by a manufacturing method of the display substrate according to an embodiment of the present disclosure.

FIG. 2 is a schematic diagram showing a first structure of a display substrate prepared by a manufacturing method of the display substrate in the prior art.

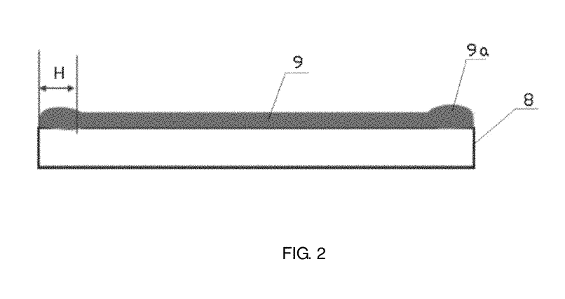

FIG. 3 is a schematic diagram showing a second structure of a display substrate prepared by a manufacturing method of the display substrate in the prior art.

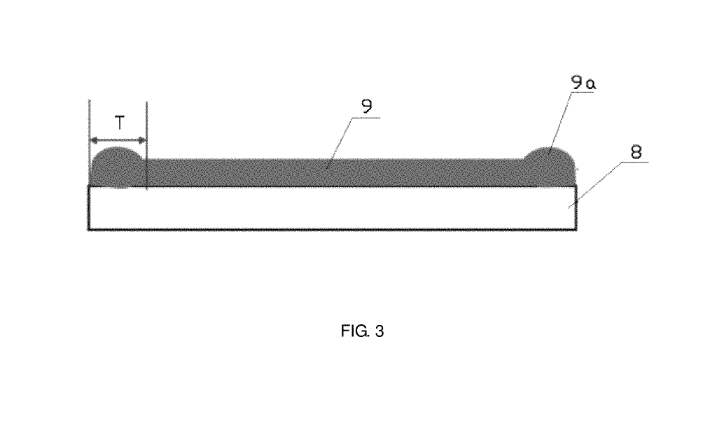

### DETAILED DESCRIPTION OF PREFERRED EMBODIMENTS

The technical solutions in the embodiments of the present disclosure will be described clearly and completely hereinafter with reference to the accompanying figures in the embodiments of the present disclosure; apparently, the described embodiments are merely a part but not all embodiments of the present disclosure.

Based on the embodiments of the present disclosure, all other embodiments obtained by persons of ordinary skill in the art without creative efforts shall fall within the protection scope of the present disclosure.

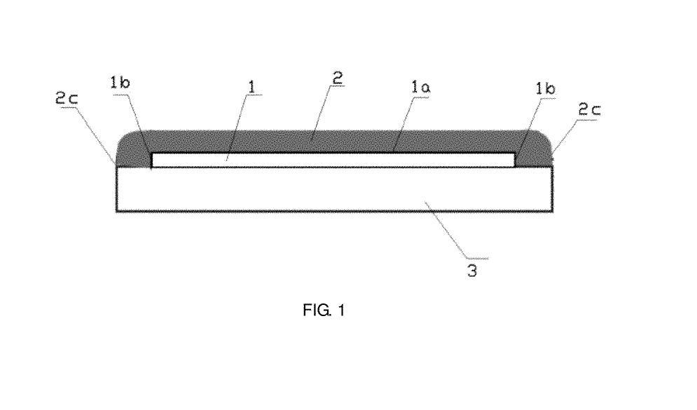

In a display substrate in an embodiment, as shown in FIG. 1, comprising: an inorganic film layer 1; a substrate film layer 2 disposed on one side surface 1a and four sides 1b of the inorganic film layer 1, wherein the substrate film layer 2 partially covers the inorganic film layer 1; and a thin film transistor, an OLED layer and an encapsulation layer disposed on the substrate film layer. Wherein a structure of the thin film transistor, the OLED layer and the encapsulation layer are consistent with those of the existing display substrate, the OLED layer and the encapsulation layer.

In practice, a material of the inorganic film layer is a silicon or a silicon dioxide, in a preferred embodiment, a thermal expansion coefficient of the material used for the inorganic film layer 1 is the same as or similar to the thermal expansion coefficient of the material used for the substrate film layer 2. For example, in the embodiment, the material of the substrate film layer 2 is a polyimide,

The thermal expansion coefficient of a selected silicon material is 2.5×10⁻⁶/K, or the thermal expansion coefficient of a selected silicon dioxide material is 0.5×10⁻⁶/K, which is similar to which the polyimide material used for the substrate film layer 2.

An effect of an arrangement is that the material of the same or similar thermal expansion coefficient can reduce a thermal stress during the manufacturing process of the substrate and reduce a probability of generating an uneven film layer at the edge of the substrate film layer 2.

In the embodiment, an area where the substrate film layer 2 partially covers the inorganic film layer 1 comprises: the area of the one surface 1a of the inorganic film layer 1 and four sides 1b of the inorganic film layer 1.

In the preferred embodiment, a distance between boundaries 1a, 1b of the inorganic film layer and the boundary of the substrate film layer 2 is in a range of 3˜10 mm, that is, the distance between the boundary 1a of the inorganic film layer 1 and the boundary 2c of the substrate film layer 2 is set to be in the range of 3˜10 mm, and/or the distance between the boundary 1b of the inorganic film layer and the boundary 2c of the substrate film layer 2 is set to be between 3˜10 mm.

The effect of the arrangement is as follows: an applicant has found through multiple experiments that when a thickness of the substrate film layer 2 is set to be different sizes, the applicant accordingly adjusts the distance range between the boundary 1a of the inorganic film layer 1 and the boundary 2c of the substrate film layer 2, and there is an obvious technical effect of improving an evenness of the edge film layer of the substrate film layer 2. When the distance between the boundaries 1a, 1b of the inorganic film layer and the boundary of the substrate film layer 2 is in the range of 3˜10 mm, and the manufacturing process of the substrate film layer 2 with a common thickness can be adapted so as to avoid an occurrence of an uneven film on the edge of the substrate film layer 2.

Preferably, the thickness of the inorganic film layer 1 is between 100˜500 nm. The effect of a setting is as follows: the applicant has found through multiple experiments that when the inorganic film layer 1 is not provided, a bump thickness of the uneven film generated at the edge of the substrate film layer 2 in the manufacturing process of the substrate film layer 2 with the common thickness is between 100˜500 nm. In this way, when the thickness of the inorganic film layer 1 is set to be equivalent to the bump thickness of the uneven film generated at the edge of a directly-disposed substrate film layer 2, that is, the thickness of the inorganic film 1 is between 100˜500 nm, which can significantly suppress the uneven film layer.

The substrate film layer 2 partially covers the inorganic film layer 1, which effectively reduces the range of the uneven area of the thickness of the edge film layer of the display substrate, and increases the utilization rate of the used area of the substrate.

The disclosure also discloses the manufacturing method of the display substrate, as shown in FIG. 1, comprising the following steps: depositing the inorganic film layer 1 on a carrier substrate 3; coating the substrate film layer 2 on the inorganic film layer 1, and coating the substrate film layer 2 on a one side surface 1a and four sides 1b of the inorganic film layer 2 to partially cover the inorganic film layer 3; preparing the thin film transistor on the substrate film layer; preparing an OLED layer on the thin film transistor; preparing an encapsulation layer on the OLED layer. Wherein, the structure and the manufacturing method of the thin film transistor, the OLED layer and the encapsulation layer are consistent with those of the existing display substrate, the OLED layer and the encapsulation layer.

In practice, the carrier substrate 3 is made of a glass; firstly, the inorganic film layer 1 is prepared on a glass substrate, which the material of the inorganic film layer is the silicon or the silicon dioxide, in the preferred embodiment, the thermal expansion coefficient of the material used for the inorganic film layer 1 is the same as or similar to the thermal expansion coefficient of the material used for the substrate film layer 2. For example, in the embodiment, the material of the substrate film layer 2 is a polyimide, and the thermal expansion coefficient of the selected silicon material is 2.5×10⁻⁶/K, or the thermal expansion coefficient of the selected silicon dioxide material is 0.5×10⁻⁶/K, which is similar to which the polyimide material used for the substrate film layer 2. The effect of the arrangement is that the material of the same or similar thermal expansion coefficient can reduce the thermal stress during the manufacturing process of the substrate and reduce the probability of generating the uneven film layer at the edge of the substrate film layer 2.

Then, the substrate film layer 2 is coated on the inorganic film layer 1 and its surrounding carrier substrate 3, that is, the area of the substrate film layer 2 is larger than the inorganic film layer 1, and the substrate film layer 2 partially covers the inorganic film layer 1. A partially-covered area comprises the area of the one side surface 1a of the inorganic film layer 1 and the area of four sides 1b of the inorganic film layer 1.

In practice, the distance between the boundaries 1a, 1b of the inorganic film layer and the boundary of the substrate film layer 2 is in a range of 3˜10 mm, that is, the distance between the boundary 1a of the inorganic film layer 1 and the boundary 2c of the substrate film layer 2 is set to be in the range of 3˜10 mm, and/or the distance between the boundary 1b of the inorganic film layer and the boundary 2c of the substrate film layer 2 is set to be between 3˜10 mm. The effect of the arrangement is as follows: the applicant has found through multiple experiments that when the thickness of the substrate film layer 2 is set to be different sizes, the applicant accordingly adjusts the distance range between the boundary 1a of the inorganic film layer 1 and the boundary 2c of the substrate film layer 2, and there is the obvious technical effect of improving the evenness of the edge film layer of the substrate film layer 2. When the distance between the boundaries 1a, 1b of the inorganic film layer and the boundary of the substrate film layer 2 is in the range of 3˜10 mm, and the manufacturing process of the substrate film layer 2 with the common thickness can be adapted so as to avoid the occurrence of the uneven film on the edge of the substrate film layer 2.

Preferably, the thickness of the inorganic film layer 1 is between 100˜500 nm. The effect of the setting is as follows: the applicant has found through multiple experiments that when the inorganic film layer 1 is not provided, the bump thickness of the uneven film generated at the edge of the substrate film layer 2 in the manufacturing process of the substrate film layer 2 with the common thickness is between 100˜500 nm. In this way, when the thickness of the inorganic film layer 1 is set to be equivalent to the bump thickness of the uneven film generated at the edge of the directly-disposed substrate film layer 2, that is, the thickness of the inorganic film 1 is between 100˜500 nm, which can significantly suppress the uneven film layer.

Moreover, further comprises: peeling off the carrier substrate 3 to form the display substrate.

In the embodiment of the manufacturing method of the display substrate, the substrate film layer 2 partially covers the inorganic film layer 1, which effectively reduces the range of the uneven area of the thickness of the edge film layer of the display substrate, and increases the utilization rate of the used area of the substrate.

The present disclosure further discloses a display device including the display substrate, which the embodiment of the display device is the same as the embodiment of the display substrate, and will not be repeated here.

The implementation of the display substrate, the manufacturing method and the display device provided by the present disclosure has the following advantages: depositing the inorganic film layer on the carrier substrate; coating the substrate film layer on the inorganic film layer, and the substrate film layer is coated on the one side surface and the periphery of the inorganic film layer to partially cover the inorganic film layer which effectively reduce the range of the uneven area of the thickness of the edge film layer of the display substrate, and increases the utilization rate of the used area of the substrate.

What is claimed is:

1. A display substrate, comprising:
an inorganic film layer;
a substrate film layer disposed on one side surface of and four sides of the inorganic film layer, wherein the substrate film layer partially covers the inorganic film layer;
a thin film transistor, an OLED layer and an encapsulation layer disposed on the substrate film layer.

2. The display substrate according to claim 1, wherein, a thermal expansion coefficient of a material used for the inorganic film layer is the same as or similar to the thermal expansion coefficient of the material used for the substrate film layer.

3. The display substrate according to claim 2, wherein the material of the inorganic film layer is a silicon or a silicon dioxide, and the material of the substrate film layer is a polyimide.

4. The display substrate according to claim 1, wherein, a thickness of the inorganic film layer is smaller than the thickness of the substrate film layer; and
the thickness of the inorganic film layer is 100˜500 nm.

5. The display substrate according to claim 1, wherein a distance between a boundary of the inorganic film layer and a boundary of the substrate film layer ranges 3˜10 mm.

6. A manufacturing method of a display substrate, comprising following steps:
depositing an inorganic film layer on a carrier substrate;
coating a substrate film layer on the inorganic film layer, and coating the substrate film layer on one side surface and four sides of the inorganic film layer to partially cover the inorganic film layer;
preparing a thin film transistor on the substrate film layer;
preparing an OLED layer on the thin film transistor;
preparing an encapsulation layer on the OLED layer.

7. The manufacturing method of a display substrate according to claim 6, wherein, further comprising:
peeling off the carrier substrate to form the display substrate.

8. The manufacturing method of a display substrate according to claim 6, wherein in the step of depositing the inorganic film layer, a thickness of the inorganic film layer is 100˜500 nm; and
a thermal expansion coefficient of a material used for the inorganic film layer is the same as or similar to the thermal expansion coefficient of the material used for the substrate film layer.

9. The manufacturing method of a display substrate according to claim 7, wherein in the step of depositing the inorganic film layer, a thickness of the inorganic film layer is 100˜500 nm; and
a thermal expansion coefficient of a material used for the inorganic film layer is the same as or similar to the thermal expansion coefficient of the material used for the substrate film layer.

10. The manufacturing method of a display substrate according to claim 6, wherein in the step of coating the substrate film layer on the inorganic film layer, a distance between a boundary of the inorganic film layer and the boundary of the substrate film layer ranges 3˜10 mm.

11. The manufacturing method of a display substrate according to claim 7, wherein in the step of coating the substrate film layer on the inorganic film layer, a distance between a boundary of the inorganic film layer and a boundary of the substrate film layer ranges 3˜10 mm.

12. A display device, comprising a display substrate, the display substrate comprising an inorganic film layer; a substrate film layer disposed on one side surface and four sides of the inorganic film layer, wherein the substrate film layer partially covers the inorganic film layer; a thin film transistor, an OLED layer and an encapsulation layer are disposed on the substrate film layer.

13. The display device according to claim 12, wherein a thermal expansion coefficient of a material used for the inorganic film layer is the same as or similar to the thermal expansion coefficient of the material used for the substrate film layer.

14. The display device according to claim 13, wherein the material of the inorganic film layer is a silicon or a silicon dioxide, and the material of the substrate film layer is a polyimide.

15. The display device according to claim 12, wherein a thickness of the inorganic film layer is smaller than the thickness of the substrate film layer;
the thickness of the inorganic film layer is 100˜500 nm.

16. The display device according to claim 12, wherein a distance between a boundary of the inorganic film layer and the boundary of the substrate film layer ranges 3˜10 mm.
